(19) United States
(12) Patent Application Publication
(10) Pub. No.: US 2023/0042805 A1
(43) Pub. Date: Feb. 9, 2023

(54) RF SWITCH DEVICE AND METHOD OF MANUFACTURING SAME

(71) Applicant: DB HiTek Co., Ltd., Bucheon-si (KR)

(72) Inventor: Jin Hyo JUNG, Suwon-si (KR)

(21) Appl. No.: 17/813,817

(22) Filed: Jul. 20, 2022

(30) Foreign Application Priority Data
Aug. 6, 2021 (KR) 10-2021-0103560

(51) Int. Cl. H01L 23/552; H01L 23/66; H01L 27/12; H01L 21/84; H01L 21/762

(52) U.S. Cl. CPC H01L 23/552; H01L 23/66; H01L 27/1203; H01L 21/84; H01L 21/76283; H01L 2223/6688

(57) ABSTRACT

Disclosed is an RF switch device and a method of manufacturing the same and, more particularly, an RF switch device and a method of manufacturing the same seeking to improve RF characteristics by forming a trap layer on a part of the surface of a substrate, thereby trapping carriers that may be on the surface of the substrate.

### CROSS REFERENCE TO RELATED APPLICATION

The present application claims priority to Korean Patent Application No. 10-2021-0103560, filed Aug. 6, 2021, the entire contents of which is incorporated herein for all purposes by this reference.

### BACKGROUND OF THE INVENTION

### Field of the Invention

The present disclosure relates to an RF switch device and a method of manufacturing the same and, more particularly, to an RF switch device and a method of manufacturing the same seeking to improve RF characteristics by forming a trap layer on a part of the surface of a substrate, thereby trapping carriers that may be generated on the surface of the substrate.

### Description of the Related Art

In general, a radio frequency front-end module (RF FEM) used in wireless communication devices such as a mobile phone, a smartphone, a notebook computer, a tablet PC, a PDA, a mobile game device, a multimedia device, etc. may include an RF active device, an RF passive device, an RF switch device, and a control device.

FIG. 1 is a reference diagram of a conventional RF switch device, and FIG. 2 is a graph comparing second harmonic distortion (HD2) characteristics of a general silicon-on-insulator (SOI) wafer, an SOI wafer using a high resistivity substrate, and an SOI wafer including a trap layer on a high resistivity substrate.

Hereinafter, the problems of an RF switch device on a conventional high resistivity SOI substrate 9 will be described in detail with reference to the accompanying drawings.

The conventional high resistivity SOI substrate 9 will be described with reference to FIG. 1. A buried oxide (BOX) layer 930 is formed on a high resistivity substrate (HRS) 910, and a silicon film (“Top Si”) 950 is formed on the BOX layer 930. The silicon film 950 is physically separated from the high resistivity substrate 910 by the BOX layer 930. However, radio frequency coupling occurs due to the parasitic capacitance formed between the high resistivity substrate 910 and the silicon film 950, and carriers may accumulate on the surface of the high resistivity substrate 910 facing the BOX layer 930. Accordingly, the surface resistance of the high resistivity substrate 910 decreases, which is referred to as parasitic surface conduction (PSC). Due to PSC, crosstalk between adjacent metal wires (e.g., on or over the silicon film 950) may occur. In addition, the resistance of the high resistivity substrate 910 may vary depending on the frequency of the input radio signal; that is, linearity of the resistance of the substrate 910 as a function of signal frequency may deteriorate.

In order to solve these problems, a trap layer 970 between the BOX layer 930 and the high resistivity substrate 910 may trap carriers on the surface side of the high resistivity substrate 910, to reduce or eliminate PSC. As such, it is possible to obtain improved RF characteristics compared to the conventional SOI substrate 9.

Referring to FIG. 2, curve A shows the second harmonic distortion (HD2) characteristics of a typical SOI wafer with a substrate resistance of 10 ohm·com, curve B shows the HD2 characteristics of an SOI wafer having a high resistivity substrate with a substrate resistance of 1,000 ohm·com, and C shows the HD2 characteristics of the SOI wafer including the trap layer 970 on a high resistivity substrate. Based on an input power of 15 dBm, the HD2 characteristics are improved by about 30 dB compared to the general SOI wafer when the high resistivity substrate 910 is present, and an additional 40 dB improvement is obtained when the trap layer 970 is present.

However, forming the trap layer 970 typically entails a complicated process, and the economical efficiency of manufacturing RF devices on such a substrate decreases due to the high cost.

Document of Related Art

Korean Patent Application Publication No. 10-2019-0127389, “SEMICONDUCTOR DEVICE AND METHOD OF MANUFACTURING SAME.”

### SUMMARY OF THE INVENTION

The present disclosure has been made to solve the problems of the related art, and objectives of the present disclosure include providing an RF switch device and a method of manufacturing the same seeking to reduce parasitic surface conduction (PSC) by forming a trap layer on a surface of a high resistivity substrate to trap carriers thereon.

In addition, objectives of the present disclosure include providing an RF switch device and a method of manufacturing the same that simplify the manufacturing process by directly forming a trap layer in and/or on the high resistivity substrate without forming a buried oxide (BOX) layer as in the related art, thereby improving economical efficiency of the manufacturing process.

According to an embodiment of the present disclosure, there is provided an RF switch device, including a high resistivity substrate having a first region including active elements and a well region, and a second, peripheral region; a gate on the high resistivity substrate in the first region; a source and a drain in the high resistivity substrate in the first region; a device isolation layer at or near a boundary between the first region and the second region; and a trap layer on a surface of the substrate in the second region.

According to another embodiment of the present disclosure, in the RF switch device, the trap layer may comprise poly-silicon or amorphous silicon.

According to still another embodiment of the present disclosure, in the RF switch device, the device isolation layer may be spaced apart from an end or side (e.g., a nearest end or sidewall) of the trap layer.

According to still another embodiment of the present disclosure, in the RF switch device, the device isolation layer may be in contact with an end or sidewall of the trap layer.

According to still another embodiment of the present disclosure, in the RF switch device, the trap layer may comprise epitaxial silicon (e.g., epitaxial poly-silicon or epitaxial amorphous silicon). According to still another embodiment of the present disclosure, in the RF switch device, the trap layer may have an end or sidewall in the first region.

According to still another embodiment of the present disclosure, there is provided an RF switch device, including a high resistivity substrate having a first region including active elements and a well region, and a second, peripheral region; a gate on the high resistivity substrate in the first region; a source and a drain in the high resistivity substrate in the first region; a device isolation layer at or near a boundary between the first region and the second region; and a trap layer on a surface of the substrate in the second region, wherein the device isolation layer may be horizontally spaced apart from the boundary between the first region and the second region and is in the well region, and the trap layer may comprise poly-silicon or amorphous silicon.

According to still another embodiment of the present disclosure, in the RF switch device, the trap layer may have an end or sidewall on the boundary between the first region and the second region.

According to still another embodiment of the present disclosure, in the RF switch device, the trap layer may have an end or sidewall in the first region (e.g., in the well region).

According to still another embodiment of the present disclosure, in the RF switch device, the trap layer may have a surface substantially flush or coplanar with a surface of the substrate in the first region.

According to an embodiment of the present disclosure, there is provided a method of manufacturing an RF switch device including forming an oxide film and a nitride film on a high resistivity substrate; etching the oxide film, the nitride film, to and the substrate (e.g., to a predetermined depth) in a second region outside a first region; forming a trap layer on the etched substrate in the second region; forming a device isolation layer at or near a boundary between the first region and the second region; and forming a well region in the first region.

According to another embodiment of the present disclosure, in the method of manufacturing an RF switch device, forming the trap layer may include epitaxially growing silicon (e.g., poly-silicon silicon or amorphous silicon) on the etched substrate in the second region.

According to still another embodiment of the present disclosure, the method of manufacturing an RF switch device may further include performing a CMP process on the substrate after forming the device isolation layer.

According to still another embodiment of the present disclosure, in the method of manufacturing an RF switch device, forming the device isolation layer may include forming a trench by etching a part of the substrate in the first region; and filling the trench with a silicon oxide film.

According to still another embodiment of the present disclosure, in the method of manufacturing an RF switch device, the device isolation layer may be formed at a position horizontally spaced apart from the adjacent boundary between the first and the second regions.

According to still another embodiment of the present disclosure, in the method of manufacturing an RF switch device, the trap layer may not overlap the first region.

The present RF switch device and method have the following effects.

The present RF switch device and method can reduce parasitic surface conduction (PSC) by forming a trap layer on a surface of a high resistivity substrate to trap carriers thereon.

In addition, the present RF switch device and method can simplify the manufacturing process by directly forming the trap layer in or on the high resistivity substrate without forming a buried oxide (BOX) layer as in the related art, thereby improving economical efficiency.

Meanwhile, it should be added that even if some effects are not explicitly mentioned herein, the effects expected from the technical features of the present disclosure and their potential further effects are treated as if they were described herein.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a reference diagram of a conventional substrate for an RF switch device;

FIG. 2 is a graph comparing HD2 characteristics of a general SOI wafer, an SOI wafer including a high resistivity substrate, and an SOI wafer including a trap layer on a high resistivity substrate;

FIG. 3 is a cross-sectional view of an RF switch device according to a first embodiment of the present disclosure;

FIG. 4 is a cross-sectional view of an RF switch device according to a second embodiment of the present disclosure;

FIG. 5 is a cross-sectional view of an RF switch device according to a third embodiment of the present disclosure; and

FIGS. 6 to 11 are reference diagrams showing structures in a method of manufacturing an RF switch device according to the first embodiment of the present disclosure.

### DETAILED DESCRIPTION OF THE INVENTION

Hereinafter, embodiments of the present disclosure will be described in more detail with reference to the accompanying drawings. The embodiments of the present disclosure may be modified in various forms, and the scope of the present disclosure should not be construed as being limited to the following embodiments, but should be construed based on the matters described in the claims. In addition, these embodiments are only provided for reference in order to more completely explain the present disclosure to those skilled in the art.

As used herein, the singular form may include the plural form unless the context clearly dictates otherwise. Furthermore, as used herein, the terms “comprise” and “comprising” refer to the specific existence of the recited shapes, numbers, steps, actions, members, elements, groups thereof, etc., and does not exclude the presence or addition of one or more other shapes, numbers, actions, members, elements, groups, etc.

Hereinafter, it should be noted that when one component (or layer) is described as being on another component (or layer), one component may be directly on the other component, or one or more third components or layers may be between the one component and the other component. In addition, when one component is expressed as being directly on or above another component, no other components are between the one component and the other component. Moreover, being located on “top,” “above,” “below,” “bottom” or a “side” of a component means a relative positional relationship.

The terms “first,” “second,” “third,” etc. may be used to describe various items such as various components, regions and/or parts. However, the items are not limited by these terms.

In addition, it should be noted that, where certain embodiments are otherwise feasible, certain process sequences may be performed other than as described below. For example, two processes described in succession may be performed substantially simultaneously or in the reverse order.

Furthermore, the conductivity or dopant type in a doped region or component may be defined as “p-type” or “n-type” according to the main carrier characteristics, but this is only for convenience of description, and the technical spirit of the present disclosure is not limited to what is illustrated. For example, hereinafter, “p-type” and “n-type” may be replaced with the more general terms “first conductivity type” and “second conductivity type.” Herein, the first conductivity type may refer to p-type, and the second conductivity type may refer to n-type.

Furthermore, it should be understood that the terms “high concentration” and “low concentration” in reference to the doping concentration of an impurity region refer to the doping concentration of one component relative to one or more other components.

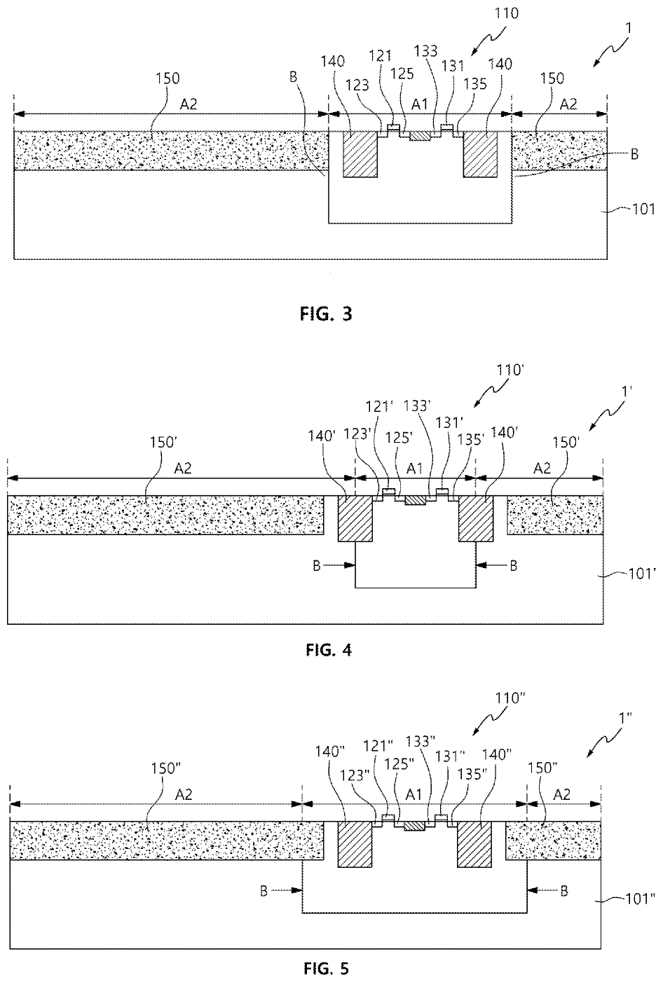

FIG. 3 is a cross-sectional view of an RF switch device according to a first embodiment of the present disclosure, FIG. 4 is a cross-sectional view of an RF switch device according to a second embodiment of the present disclosure, and FIG. 5 is a cross-sectional view of an RF switch device according to a third embodiment of the present disclosure.

Hereinafter, an RF switch device 1 according to the first embodiment of the present disclosure will be described in detail with reference to the accompanying drawings.

Referring to FIG. 3, the present disclosure relates to an RF switch device 1 and, more particularly, to an RF switch device 1 seeking to improve RF characteristics by forming a trap layer on part of the surface of a substrate 101, thereby trapping carriers that may be on the surface of the substrate 101.

The RF switch device 1 is on and/or in a high resistivity substrate 101. The substrate 101 may comprise a silicon substrate. To be specific, the substrate 101 may be lightly doped with a first conductivity type impurity such as B or In, or a second conductivity type impurity such as P or As. In addition, it is preferable that the substrate 101 has a resistivity of about 1,000 ohm·cm or more, and more preferable that the substrate 101 has a resistivity of 1,000 ohm·cm or more and 20,000 ohm·cm or less, but is not limited thereto.

The switch device 1 includes a first region A1 including active elements and a well region, and a second region A2 which is a peripheral area. One or more field effect transistors 110 may be in the first region A1. A plurality of field effect transistors 110 may be spaced apart from each other in the first region A1. Each transistor 110 may include a source, a drain, and a gate on the surface of the substrate. In general, sources and drains in field effect transistors may be referred to as “source/drain terminals.”

For example, a plurality of gates 121 are on the surface of the substrate 101, and a source 123 and a drain 125 having the second conductivity type are on the surface of and/or in the substrate 101 on opposite sides of a first gate 121. A well region having the first conductivity type (not shown, or perhaps not identified) may be in the substrate 101 and may surround the source 123 and the drain 125 having the second conductivity type.

In addition, a source 133 and a drain 135 having the first conductivity type are on the surface of and/or in the substrate 101 on opposite sides of a second gate 131. A well region having the second conductivity type (not shown, or perhaps not identified) may be in the substrate 101 and may surround the source 133 and the drain 135 having the first conductivity type. As such, complementary metal-oxide semiconductor (CMOS) devices may be in the first region A1, but there is no particular limitation thereto, and the scope of the present disclosure is not limited by the above examples.

In addition, a device isolation layer 140 defining the active region may be at or proximate to the boundary B between the first region A1 and the second region A2. The device isolation layer 140 may be formed by shallow trench isolation (STI), and may comprise, for example, a silicon oxide (e.g., undoped silicon dioxide). The device isolation layer 140 may be at or near the boundary B between the first region A1 and the second region A2.

In the first embodiment, the device isolation layer 140 may be near or proximate to the boundary B between the first region A1 and the second region A2, in the first region A1. Alternatively, referring to FIG. 4, in the second embodiment, the device isolation layer 140′ may be at the boundary B to overlap the first region A1 and the second region A2. In the case of the first embodiment, a relatively easy process of forming the device isolation layer 140 is possible by allowing a space between the boundary B and the adjacent device isolation layer 140. In the case of the second embodiment, there is an advantage in avoiding wasted space (i.e., space between the device isolation layer 140′ and the adjacent boundary B) in the well region in the first region A1.

In the second region A2, a trap layer 150 is on the surface of the substrate 101. The trap layer 150 may be formed by epitaxial growth of silicon (e.g., poly-silicon or amorphous silicon), for example. The surface of the second region A2 (e.g., containing the trap layer 150) may have a height substantially equal to or similar to that of the surface of the first region A1. In other words, the uppermost surfaces of the second region A2 (e.g., the trap layer 150) and the first region A1 (e.g., the device isolation layer[s] 140 and the active area therein) may be coplanar or substantially coplanar.

Referring to FIG. 3, in the first embodiment, the trap layer 150 may extend to the boundary between the first region A1 and the second region A2. In other words, the trap layer 150 does not extend into or overlap the well region in the first region A1. Alternatively, referring to FIG. 4, in the second embodiment, when the device isolation layer 140′ extends to or into the second region A2 adjacent to the boundary B, the trap layer 150 may extend to the end or sidewall of the device isolation layer 140 or be spaced therefrom. Finally, referring to FIG. 5, in the third embodiment, when the device isolation layer 140″ is only in the first region A1, the trap layer 150″ may extend into or overlap part of the first region A1. In the third embodiment, the trap layer 150″ may extend to the end or sidewall of the adjacent device isolation layer 140″ or be spaced therefrom.

Hereinafter, the conventional high resistivity substrate 9 for the RF switch device and problems thereof will be described in detail once again.

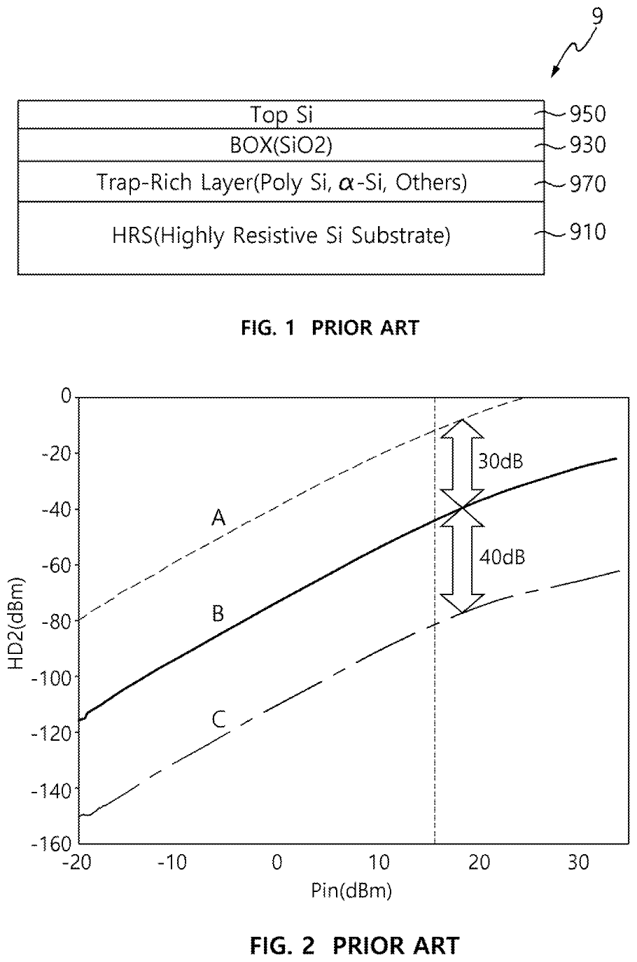

The conventional substrate 9 will be described with reference to FIG. 1. A buried oxide (BOX) layer 930 is on or in a high resistivity substrate (HRS) 910, and a silicon film 950 is on the BOX layer 930. At this time, the silicon film 950 is physically separated from the high resistivity substrate 910 by the BOX layer 930. However, radio frequency coupling may occur due to the parasitic capacitance between the high resistivity substrate 910 and the silicon film 950, and carriers may accumulate on the surface of the high resistivity substrate 910 facing the BOX layer 930. Accordingly, the surface resistance of the high resistivity substrate 910 decreases, which is referred to as parasitic surface conduction (PSC). Due to this PSC, crosstalk between adjacent metal wires (e.g., on or over the silicon film 950) may occur. In addition, the resistance level of the high resistivity substrate 910 may vary depending on the input radio frequency signal; that is, linearity may deteriorate.

In order to solve these problems, a trap layer 970 between the BOX layer 930 and the high resistivity substrate 910 may trap carriers on the surface of the high resistivity substrate 910. As such, it is possible to obtain improved RF characteristics compared to the conventional structure.

Referring to FIG. 2, curve A shows the second harmonic distortion (HD2) characteristic of a typical SOI wafer with a substrate resistance of 10 ohm·com, curve B shows the HD2 characteristic of an SOI wafer including a high resistivity substrate with a substrate resistance of 1,000 ohm·com, and curve C shows the HD2 characteristics of the SOI wafer including the trap layer 970 on a high resistivity substrate. Based on input power of 15 dBm, the HD2 characteristic is improved by about 30 dB compared to the general SOI wafer when the high resistivity substrate 910 is present, and an additional 40 dB improvement is obtained when the trap layer 970 is present.

However, forming the trap layer 970 typically entails a complicated process, and the economical efficiency of manufacturing RF devices on such a substrate decreases due to the high cost.

Referring to FIG. 3, in order to avoid such problems, the RF switch device 1 according to the first embodiment of the present disclosure includes a trap layer 150 on the surface of the high resistivity substrate 101 in the second region A2, outside the first region A1. Unlike the conventional structure, the RF switch device 1 includes the trap layer 150 directly on and/or in the high resistivity substrate 101, and a separate BOX layer is not present or necessary. This promotes simplification of the manufacturing process. In other words, the structure does not include a plurality of layers on the high resistivity substrate 101, but merely the trap layer 150 on or in the high resistivity substrate 101. In addition, since the trap layer 150 is directly on the surface of the substrate 101 instead of under the device isolation layer in the second region A2, an advantage may occur in the manufacturing process.

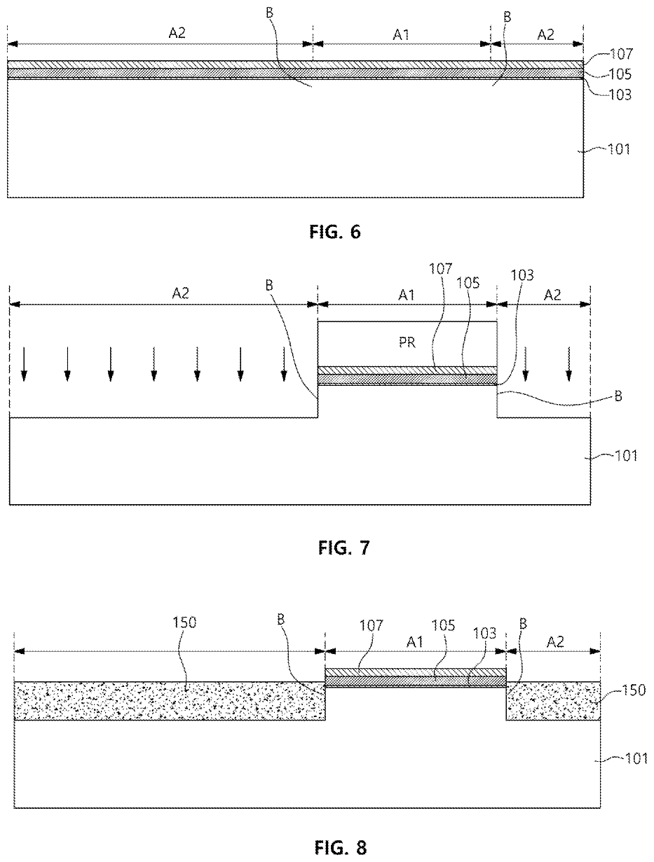

FIGS. 6 to 11 are reference diagrams regarding a method of manufacturing an RF switch device according to the first embodiment of the present disclosure.

Hereinafter, a method of manufacturing an RF switch device according to one or more embodiments of the present disclosure will be described in detail with reference to the accompanying drawings.

First, referring to FIG. 6, a sacrificial oxide layer (e.g., a conventional PAD oxide) 103 is grown (e.g., by thermal oxidation of the silicon substrate 101) on the high resistivity substrate 101, and a silicon nitride film 105 is deposited on the sacrificial oxide layer 103. The sacrificial oxide layer 103 and the silicon nitride film 105 may be formed on the substrate 101 in the first region A1 and the second region A2. An additional silicon oxide film 107 may be deposited on the silicon nitride film 105, as needed or desired. Hereinafter, when it is described that a specific configuration is formed, deposited or applied on the silicon nitride film 105, it may be understood that in some cases, the configuration is formed, deposited or applied on the silicon oxide film 107.

Then, referring to FIG. 7, the substrate 101 in the second region A2 is etched to form a step at the boundary B with the first region A1. For example, after a photoresist (PR) pattern is formed on the first region A1, an etching process may be performed on the substrate 101 using the photoresist pattern PR as a mask. The etching process may first etch the oxide film 107, the silicon nitride film 105 and the sacrificial oxide layer 103 in the second region A1, followed by etching the entire surface of the substrate 101 in the second region A1. A trap layer 150 to be described later may be formed in the etched space. In addition, the etching process is preferably performed to a depth in the range of about 500 to 20,000 Å, inclusive, but is not limited thereto.

Thereafter, referring to FIG. 8, the trap layer 150 may be formed by selectively depositing silicon (e.g., a poly-silicon or amorphous silicon layer) on the exposed surfaces of the high resistivity substrate 101 in the second region A2. The trap layer 150 may be formed, for example, by epitaxial growth. As described above, in the first embodiment, the trap layer 150 may extend to the boundary B between the first region A1 and the second region A2. Alternatively, in the second embodiment, when the device isolation layer 140′ is at least partially in the second region A2 (e.g., over the boundary B), the trap layer 150 may extend to the end or sidewall of the device isolation layer 140′ or be spaced therefrom. Finally, in the third embodiment, when the device isolation layer 140″ is formed only in the first region A1, the trap layer 150″ may extend to a position in the first region A1.

Thereafter, the device isolation layer 140 is formed in the first region A1. Referring to FIG. 9, for example, a photoresist (PR) is deposited on the entire substrate 101, then a pattern is formed in the first region A1 to expose areas of the nitride film 105 or oxide film 107 corresponding to locations of the device isolation layer 140. A trench T is formed in the exposed areas of the substrate 101 by etching (e.g., conventional dry etching or reactive ion etching) near the second region A2.

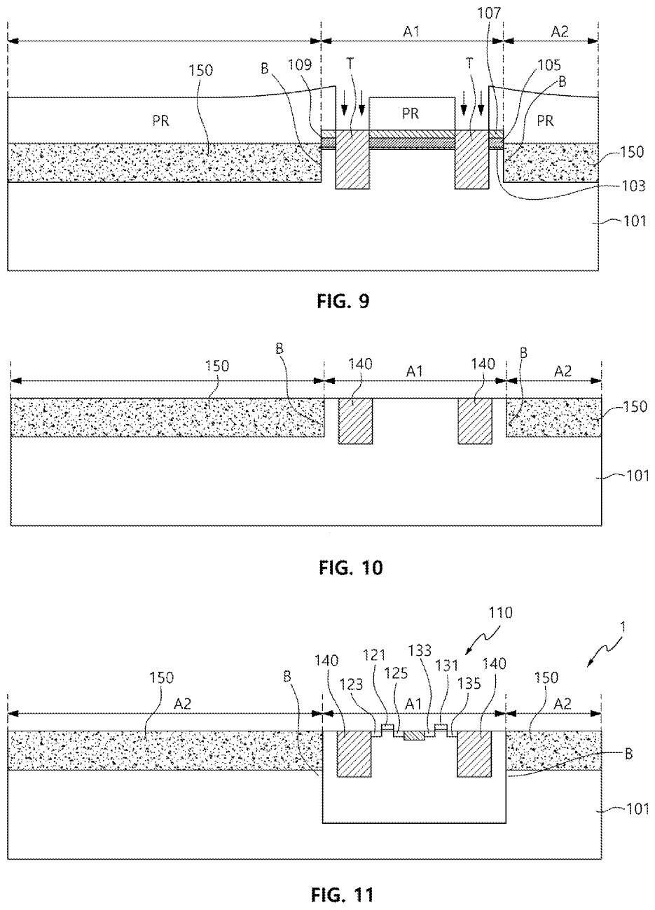

Thereafter, referring to FIG. 10, the device isolation layer may be formed by filling the trench T with a silicon oxide (e.g., undoped silicon dioxide, a silicon oxide formed from tetraethyl orthosilicate [TEOS], etc.). As previously mentioned, the device isolation layer 140 may be formed in the first region A1 near the boundary B between the first region A1 and the second region A2. Alternatively, as in the second embodiment, the device isolation layer 140′ may be formed at the boundary B, in both the first region A1 and the second region A2. Therefore, the device isolation layer 140 may be formed by forming a photoresist PR pattern exposing areas of the substrate 101 in which the device isolation layer 140 is to be formed, then etching the substrate 101 to form one or more trenches, and then filling the trench(es). After the device isolation layer 140 is formed, the excess silicon oxide (from filling the trench[es]), the oxide film 107, the nitride film 105, and the oxide film 103 are removed by chemical mechanical polishing (CMP).

Thereafter, referring to FIG. 11, CMOS devices including the gates 121 and 131, the sources 123 and 133, the drains 125 and 135, and the well region(s) having the first and/or second conductivity type(s) are conventionally formed in the first region A1.

The above detailed description is illustrative of the present disclosure. In addition, the above description shows and describes preferred embodiments of the present disclosure, and the present disclosure can be used in various other combinations, modifications, and environments. That is, changes or modifications are possible within the scope of the concept of the disclosure disclosed herein, the scope equivalent to the written disclosure, and/or within the scope of skill or knowledge in the art. The above-described embodiment describes the best state for implementing the technical idea of the present disclosure, and various changes useful in a specific application and/or field and other uses of the present disclosure are possible. Accordingly, the detailed description of the present disclosure is not intended to limit the present disclosure to the disclosed embodiments.

What is claimed is:

1. An RF switch device, comprising:
a high resistivity substrate having a first region including active elements and a well region, and a second, peripheral region;
a gate on the high resistivity substrate in the first region;
a source and a drain in the high resistivity substrate in the first region;
a device isolation layer at or near a boundary between the first region and the second region; and
a trap layer on a surface of the substrate in the second region.

2. The RF switch device of claim 1, wherein the trap layer comprises poly-silicon or amorphous silicon.

3. The RF switch device of claim 2, wherein the device isolation layer is spaced apart from a nearest end or sidewall of the trap layer.

4. The RF switch device of claim 2, wherein the device isolation layer is in contact with an end or sidewall of the trap layer.

5. The RF switch device of claim 2, wherein the trap layer comprises epitaxial silicon.

6. The RF switch device of claim 2, wherein the trap layer has an end or sidewall in the first region.

7. An RF switch device, comprising:
a high resistivity substrate having a first region including active elements and a well region, and a second, peripheral region;
a gate on the high resistivity substrate in the first region;
a source and a drain in the high resistivity substrate in the first region;
a device isolation layer at or near a boundary between the first region and the second region; and
a trap layer on a surface of the substrate in the second region,
wherein the device isolation layer is horizontally spaced apart from the boundary between the first region and the second region and is in the well region, and
the trap layer comprises poly-silicon or amorphous silicon.

8. The RF switch device of claim 7, wherein the trap layer has an end or sidewall on the boundary between the first region and the second region.

9. The RF switch device of claim 7, wherein the trap layer has an end or sidewall of which is in the first region.

10. The RF switch device of claim 7, wherein the trap layer has a surface substantially flush or coplanar with a surface of the substrate in the first region.

11. A method of manufacturing an RF switch device, the method comprising:
forming an oxide film and a nitride film on a high resistivity substrate;
etching the oxide film, the nitride film and the substrate in a second region outside a first region;
forming a trap layer on the etched substrate in the second region;
forming a device isolation layer at or near a boundary between the first region and the second region; and
forming a well region in the first region.

12. The method of claim 11, wherein forming the trap layer comprises:
epitaxially growing silicon on the etched substrate in the second region.

13. The method of claim 12, wherein the silicon comprises poly-silicon or amorphous silicon.

14. The method of claim 12, further comprising:
performing a CMP process on the substrate after forming the device isolation layer.

15. The method of claim 12, wherein forming the device isolation layer comprises:
forming a trench by etching a part of the substrate in the first region; and
filling the trench with a silicon oxide film.

16. The method of claim 12, wherein the device isolation layer is formed at a position horizontally spaced apart from the boundary between the first and the second regions.

17. The method of claim 12, wherein the trap layer is not in the first region.
